(19) United States
(12) Patent Application Publication
(10) Pub. No.: US 2010/0118181 A1
(43) Pub. Date: May 13, 2010

(54) ELECTRONIC APPARATUS

(75) Inventor: Makoto Hirata, Yawata-shi (JP)

Correspondence Address: NOVAK DRUCE + QUIGG LLP, 1300 EYE STREET NW, SUITE 1000 WEST TOWER, WASHINGTON, DC, 20005, US

(73) Assignee: Sanyo Electronic Co., Ltd., Osaka (JP)

(21) Appl. No.: 12/615,620

(22) Filed: Nov. 10, 2009

(30) Foreign Application Priority Data
Nov. 11, 2008 (JP) 2008288996

(51) Int. Cl. H04N 5/225; H03L 7/00

(52) U.S. Cl. 348/372; 327/143; 348/E05.024

(57) ABSTRACT

Provided are: a determiner which determines whether or not a power-source connecting operation for transitioning to a connected state between a power source and a apparatus main body is performed; a start-up acceptor which accepts a manipulation for executing a start-up process for transitioning the apparatus main body from a non-activated state to an activated state; a non-volatile memory which holds start-up information necessary for executing the start-up process to the apparatus main body; a volatile memory; a transferer which executes a transfer operation for transferring the start-up information from the non-volatile memory to the volatile memory; a start-up processor which executes the start-up process to the apparatus main body by using the start-up information transferred, according to the start-up manipulation by the transferer, to the volatile memory; and a controller which executes the transfer operation when it is determined by the determiner that the battery mounting operation is performed.

### CROSS REFERENCE OF RELATED APPLICATION

The disclosure of Japanese Patent Application No. 2008-288996, which was filed on Nov. 11, 2008, is incorporated herein by reference.

### BACKGROUND OF THE INVENTION

1. Field of the Invention

The present invention relates to an electronic apparatus, and relates to an electronic apparatus in which power from a power source is supplied to an apparatus main body, thereby realizing shortening a start-up time period at a time of starting up.

2. Description of the Related Art

Conventionally, in an electronic apparatus such as a digital camera, for example, when a power-source off state (when a main switch is turned off) that no power is supplied to a whole apparatus except for some functions is changed to a power-source on state that the power is supplied to the whole apparatus by turning on the main switch, it requires a constant time period until a state capable of actually photographing is established. Reasons for requiring a constant time period in this manner include that which after transition from the power-source off state to the power-source on state, there is a need of executing a process for loading (developing) information, accommodated in a non-volatile memory, necessary for starting-up the apparatus main body (in this case, that information includes setting information necessary for a photographing process) into a volatile memory such as an SDRAM, and other similar processes.

When a user uses such an electronic apparatus, the shorter the time period since the transition from the power-source off state of the apparatus main body to the power-source on state thereof until the apparatus main body is actually started-up, the more convenient the usability becomes. Thus, it is demanded to shorten the time period since the transition from the power-source off state to the power-source on state until the start-up.

The conventional digital camera is capable of developing the information necessary for the photographing process into a storer such as an SDRAM so as to allow a state that a system start-up process is completed to continue even to a state that the power source is turned off. Thus, also when the user inputs the power source in order to start photographing, the user is capable of promptly starting photographing.

Then, there is a case in the digital camera that after a main switch is turned off, a user removes a primary battery or a secondary battery from a casing and mounts that battery again in a state that a voltage of the battery is secured. In this case, since the battery is removed, the conventional digital camera is not capable of allowing the storer to maintain the information necessary for starting-up the digital camera main body (system start-up process, which includes the photographing process). Therefore, when the user mounts the battery, the photographing process becomes enabled only after the following operations: the main switch is firstly turned on, the information necessary for the system start-up process is developed into an SDRAM, and thereafter, the system start-up process is completed. Generally, when the user acts to mount the battery, the user is probably in a state of mind wishing to photograph immediately. Thus, a time period taken for the system start-up process executed after turning on the main switch is very troublesome for the user.

### SUMMARY OF THE INVENTION

An electronic apparatus according to the present invention, comprises: a power-source connecting portion which connects a power source with an apparatus main body; a determiner which determines whether or not a power-source connecting operation for transitioning from a non-connected state between the power source and the apparatus main body to a connected state is performed; a start-up acceptor which accepts a manipulation for executing a start-up process for transitioning the apparatus main body from a non-activated state to an activated state; a non-volatile memory which holds start-up information necessary for executing the start-up process to the apparatus main body; a volatile memory; a transferer which executes a transfer operation for transferring the start-up information from the non-volatile memory to the volatile memory; a start-up processor which executes the start-up process to the apparatus main body by using the start-up information transferred, according to the start-up manipulation by the transferer, to the volatile memory; and a controller which executes the transfer operation when it is determined by the determiner that the battery mounting operation is performed.

Preferably, further comprised is a power supplier which supplies the non-volatile memory with power allowing the start-up information transferred by the transferer to be held for a predetermined time period.

Preferably, an imaging apparatus, comprising an imaging function as an electronic apparatus, wherein the start-up information is software used for starting up the imaging apparatus.

The above described features and advantages of the present invention will become more apparent from the following detailed description of the embodiment when taken in conjunction with the accompanying drawings.

### BRIEF DESCRIPTION OF THE DRAWINGS

FIG. 1 is a block diagram showing a digital camera according to this embodiment;

FIG. 2 is a flowchart showing one portion of operations of a sub-microcomputer and a CPU applied to this embodiment; and

FIG. 3 is a flowchart showing another portion of the operations of the sub-microcomputer and the CPU applied to this embodiment.

### DETAILED DESCRIPTION OF THE PREFERRED EMBODIMENTS

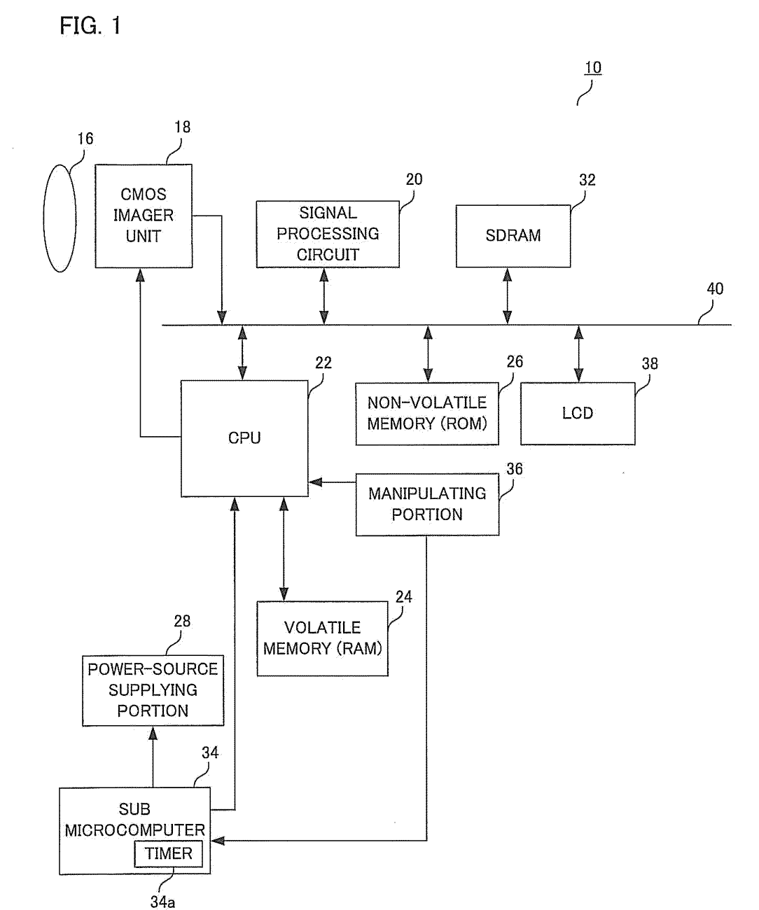

Hereinafter, as one embodiment of an electronic apparatus of the present invention, an embodiment carried out for a digital camera 10 will be described along with the drawings. FIG. 1 shows a block diagram of the digital camera 10.

The digital camera 10 includes an optical lens 16 and an aperture not shown. An optical image of a subject is fetched into a CMOS imager unit 18 through the optical lens 16 and the aperture controlled by a motor driving portion not shown by an instruction of a CPU 22. Then, by a fetching pulse applied by a timing generator (not shown) connected to the CPU 22, one frame of digital imaging signal is outputted from the CMOS imager unit 18. Herein, in the CMOS imager unit 18, electric charges accumulated in each pixel are amplified and read out as a signal from each pixel by using a wiring. Then, the signal is subjected to a correlated double sampling process, a gain adjustment, a clamping process, and an A/D converting process. The resultant digital imaging signal has a color signal (either one of R, G, or B) for each pixel, and by control of the CPU 22, is once accommodated in an SDRAM 32 via a bus 40.

The digital imaging signal once accommodated in the SDRAM 32 is inputted into a signal processing circuit 20 by control of the CPU 22. In the signal processing circuit 20, a color separation process is performed on the inputted digital imaging signal, and furthermore, by a YUV conversion, the resultant signal is converted into Y, U, and V signals. Then, the digital image signal converted by the signal processing circuit 20 is accommodated in the SDRAM 32 again via the bus 40. In this embodiment, a process performed from the digital imaging signal outputted from the above-described CMOS imager unit 18 is subjected to a converting process into the digital image signal by the signal processing circuit 20 until the resultant signal is accommodated in the SDRAM 32 is defined as a photographing process.

Moreover, the digital image signal accommodated in the SDRAM 32 is outputted by control of the CPU 22 to an LCD 38. The LCD 38 includes an LCD driver not shown. The LCD driver converts the Y, U, and V signals into an RGB signal, and causes the LCD 38 to display an image signal that is based on the digital image signal.

By the way, a manipulating portion 36 is provided with a main switch which switches on/off operations (transitions a current state from an on state to an off state or from the off state to the on state) of a power supply from a power source to a main body of the digital camera 10. It is noted that in this embodiment, a source of the power supplied to one portion or a whole of the digital camera 10 is a battery. Then, when the on/off operation of the power source of the main switch is manipulated by a user, the power supply from the power source is transitioned from the on state to the off state or the power supply from the power source is transitioned from the off state to the on state. The manipulating portion 36 is connected to a sub microcomputer 34 and the CPU 22, and when the manipulating portion 36 is manipulated, a manipulation signal including a signal corresponding to the on/off manipulation of the power source of the main switch is inputted into the CPU 22 or the sub microcomputer 34.

Furthermore, in this embodiment, a state that the power is supplied from the power source to the sub microcomputer 34 only is defined as a sub-power-source supplied state; a state that the power is supplied from the power source to the whole digital camera 10 is defined as a main-power-source supplied state; and a state that the power is not supplied from the power source to the sub microcomputer 34 and the whole digital camera 10 is defined as a power-source-supply stopped state. The power-source-supply stopped state corresponds to a state that the battery is removed from the digital camera 10, i.e., a non-battery-mounted state.

The sub microcomputer 34 is connected to a power-source supplying portion 28 and the CPU 22, and when the power-source on manipulation of the main switch of the manipulating portion 36 is performed, controls the power-source supplying portion 28 so as to supply the power from the power source to the whole digital camera 10, resulting in transition of a current state to the main-power-source supplied state. Moreover, inside the sub microcomputer 34, a timer 34a is accommodated, and when the timer 34a counts a predetermined time period, the tinier 34a outputs a time-up signal, and the sub microcomputer 34 raises a time-up flag (F=1) accommodated in a register (not shown) within the sub microcomputer 34.

Furthermore, in the digital camera 10, in a state that the battery is not mounted, the power-source-supply stopped state is established, and in a state that the battery is mounted and the power-source off manipulation of the main switch is performed, the sub microcomputer 34 controls the power-source supplying portion 28 so that the sub-power-source supplied state is established.

In a state that the battery is mounted and the power-source on manipulation of the main switch is performed, the sub microcomputer 34 controls the power-source supplying portion 28 so that the main-power-source supplied state is established.

Hereinafter, a transition of a state of the power supply from the power source will be described in detail.

In the power-source-supply stopped state, i.e., the non-battery mounted state, when the battery is mounted, the sub microcomputer 34 is supplied with the power. As a result, the sub-power-source supplied state is established. In this sub-power-source supplied state, when the power-source on manipulation of the main switch of the manipulating portion 36 is performed, the sub microcomputer 34 controls the power-source supplying portion 28 so as to supply the power to the whole digital camera 10, resulting in transition of the current state to the main-power-source supplied state. Along with the transition to the main-power-source supplied state, the CPU 22 is also supplied with the power. Then, the CPU 22 causes a firmware accommodated in a non-volatile memory 26 to develop into a volatile memory 24. The firmware is software, i.e., a program, necessary for starting-up the main body of the digital camera 10 (system start-up process, which includes the above-described photographing process).

Moreover, the sub microcomputer 34 controls the power-source supplying portion 28 so that the current state is transitioned to the sub-power-source supplied state, and also, supplies the power to the volatile memory 24 so that the developed firmware is held therein for a predetermined time period. This state is defined as a sub-power-source/firmware held state.

In the sub-power-source/firmware held state, when the power-source on manipulation of the main switch of the manipulating portion 36 is performed by the user, the CPU 22 performs the system start-up process by executing the firmware developed in the volatile memory 24. Thus, in the sub-power-source/firmware held state, since the firmware is held in a state of being developed in the volatile memory 24, when the power-source on manipulation of the main switch is performed, a process for developing the firmware accommodated in the non-volatile memory 26 into the volatile memory 24 is omitted. That is, a required time period from a time point at which the battery is mounted in the digital camera 10 and the power-source on manipulation is performed by the user until the system start-up process is executed is omitted.

Generally, an action for a user to mount a battery is often linked to a state of mind that the user wishes to immediately manipulate the digital camera 10. Therefore, because the system start-up process of the digital camera 10 is executed immediately after the power-source on manipulation of the main switch is performed, it is possible to relieve a stress that the user is not capable of immediately manipulating the digital camera 10.

Moreover, inside the sub microcomputer 34, the timer 34a is installed. When the power-source on manipulation of the main switch of the manipulating portion 36 is performed, counting of the timer 34a is started at a timing at which the current state is transitioned from the sub-power-source supplied state to the main-power-source supplied state.

Then, after an elapse of a predetermined time period, e.g., five minutes, the time-up flag is raised (F=1). When the sub microcomputer 34 senses that the time-up flag is raised (F=1), the power-supply supplying portion 28 is controlled so that supplying of the power to the volatile memory 24 is stopped, resulting in transition of the current state to the sub-power-source supplied state. As a result, the volatile memory 24 becomes unable to hold the firmware. Therefore, in the sub-power-source supplied state, when the power-source on manipulation of the main switch is performed by the user, the sub microcomputer 34 controls the power-supply supplying portion 28 so that the power is supplied to the whole digital camera 10, resulting in transition of the current state to the main-power-source supplied state. Thereafter, along with transition to the main-power-source supplied state, the CPU 22 also is supplied with the power. The CPU 22 develops the firmware accommodated in the non-volatile memory 26, into the volatile memory 24. Then, the CPU 22 executes the system start-up process by executing the developed firmware.

Thus, in a case that the power-source on manipulation by the user is not performed during a predetermined time period from a time point at which the battery is mounted by the user, it is possible to prevent unnecessary power consumption by stopping supplying of the power to the volatile memory 24.

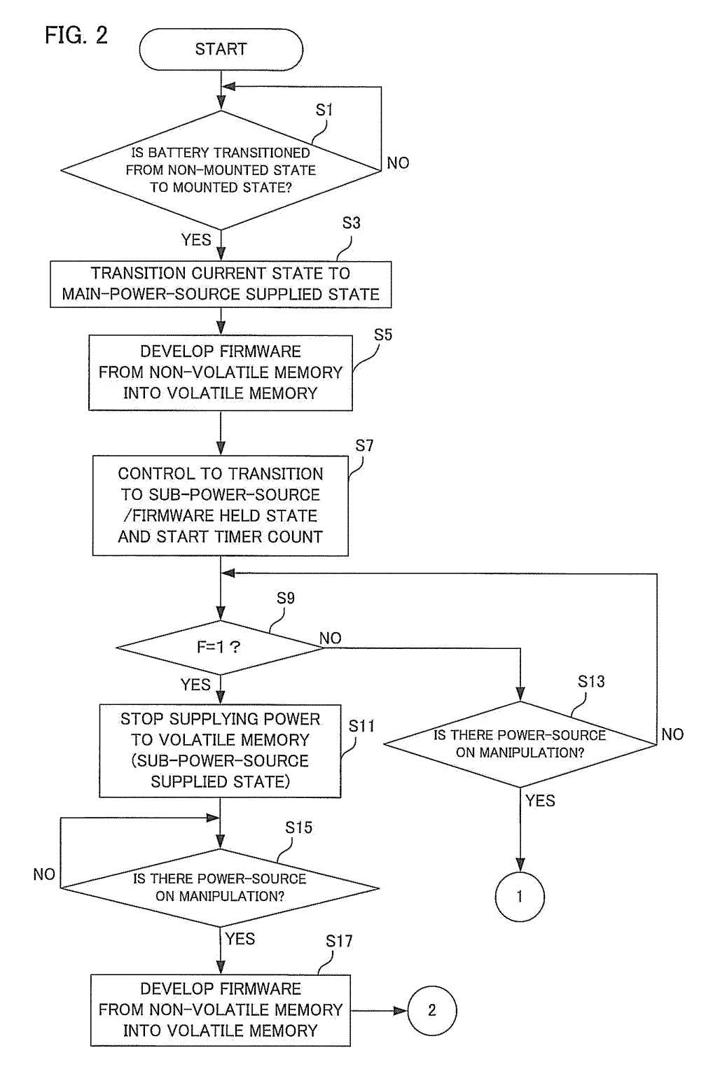

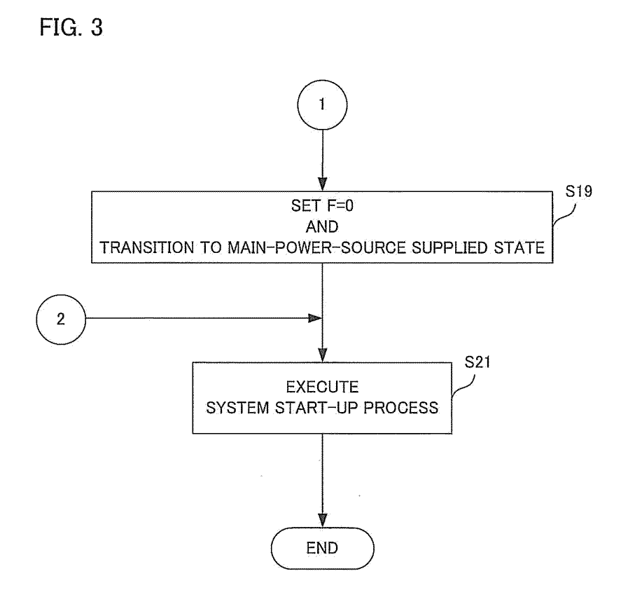

Subsequently, a procedure for the process for developing, along with mounting the battery, the firmware accommodated in the non-volatile memory 26, into the volatile memory 24 in the above-described sub microcomputer 34 and CPU 22 will be described with reference to FIG. 2 and FIG. 3.

In a step S1, the sub microcomputer 34 determines whether or not the battery is transitioned from a non-mounted state to a mounted state. In other words, whether or not the sub microcomputer 34 is supplied with the power from the power source (battery) is determined. When YES is determined in the step S1, the process advances to a step S3 so as to control the power-supply supplying portion 28 so that the current state is transitioned to the main-power-source supplied state. Then, the process advances to a step S5 in which the CPU 22 loads, i.e., develops, the firmware accommodated in the non-volatile memory 26, into the volatile memory 24.

Subsequently, the process advances to a step S7 in which the sub microcomputer 34 controls the power-supply supplying portion 28 so that the current state is transitioned to the sub-power-source/firmware held state, and also, starts counting the predetermined time period in the timer 34a within the sub microcomputer 34. Then, the process advances to a step S9 in which the sub microcomputer 34 determines whether or not the timer 34a has counted the predetermined time period, i.e., whether or not the time-up flag is raised (whether or not F=1 is established).

When the sub microcomputer 34 determines YES in the step S9, the process advances to a step S11 so as to control the power-supply supplying portion 28 so that supplying the power to the volatile memory 24 is stopped. That is, the digital camera 10 is transitioned from the sub-power-source/firmware held state to the sub-power-source supplied state, and then, the process advances to a step S15.

In the step S15, the sub microcomputer 34 determines whether or not the power-source on manipulation of the main switch by the user is performed, and when YES is determined, the process advances to a step S17. In the step S17, the CPU 22 loads, i.e., develops, the firmware accommodated in the non-volatile memory 26, into the volatile memory 24. Then, the process advances to a step S21.

When the sub microcomputer 34 determines NO in the step S9, the process advances to a step S13 so as to determine whether or not there is the power-source on manipulation of the main switch of the manipulating portion 36. When NO is determined, the process returns to the step S9 and when YES is determined, the process advances to a step S19.

In the step S19, the sub microcomputer 34 resets (F=0) the time-up flag and controls the power-supply supplying portion 28 so that the digital camera 10 is transitioned to the main-power-source supplied state. Then, the process advances to the step S21 in which the CPU 22 executes the firmware developed into the volatile memory, i.e., executes the system start-up process. Thus, the procedure is ended.

As described above, according to this embodiment, when the user mounts the battery onto the digital camera 10, the firmware is automatically developed from the non-volatile memory 26 into the volatile memory 24, and also, the firmware developed into the volatile memory 24 is held for a predetermined time period. Thereby, it becomes possible to immediately execute the firmware, i.e., execute the system start-up process, when the power-source on manipulation performed by the user is performed. Therefore, when the battery is mounted by the user and the power-source on manipulation is continuously performed, it is possible to execute the system start-up process in a short time period.

It is noted that the source of the power, i.e., the power source, supplied to the digital camera 10 in this embodiment is the battery. However, the source may be optionally selected from power sources such as an AC adaptor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. An electronic apparatus, comprising:
a power-source connecting portion which connects a power source with an apparatus main body;
a determiner which determines whether or not a power-source connecting operation for transitioning from a non-connected state between the power source and the apparatus main body to a connected state is performed;
a start-up acceptor which accepts a manipulation for executing a start-up process for transitioning the apparatus main body firm a non-activated state to an activated state;
a non-volatile memory which holds start-up information necessary for executing the start-up process to the apparatus main body;
a volatile memory;
a transferer which executes a transfer operation for transferring the start-up information from said non-volatile memory to said volatile memory;
a start-up processor which executes the start-up process to the apparatus main body by using the start-up information transferred, according to the start-up manipulation by said transferer, to said volatile memory; and
a controller which executes the transfer operation when it is determined by said determiner that the battery mounting operation is performed.

2. An electronic apparatus according to claim 1, further comprising a power supplier which supplies said non-volatile memory with power allowing the start-up information transferred by said transferer to be held for a predetermined time period.

3. An imaging apparatus, comprising an imaging function as an electronic apparatus according to claim 1, wherein the start-up information is software used for starting up said imaging apparatus.
